(19) United States
(12) Patent Application Publication
(10) Pub. No.: US 2010/0118560 A1
(43) Pub. Date: May 13, 2010

(54) CAPACITANCE-TYPE SENSOR

(75) Inventors: Tsuyoshi HAYAMA, Miyagi-ken (JP); Masami AIHARA, Miyagi-ken (JP); Manabu SHIMAOKA, Miyagi-ken (JP); Hisato SHIMOMURA, Miyagi-ken (JP); Katsumi MYOCHIN, Miyagi-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/687,818

(22) Filed: Jan. 14, 2010

Related U.S. Application Data
(63) Continuation of application No. PCT/JP2008/063877, filed on Aug. 1, 2008.

(30) Foreign Application Priority Data
Aug. 7, 2007 (JP) 2007-205142

(51) Int. Cl. G02B 6/00; G01R 27/26

(52) U.S. Cl. 362/551; 324/661

(57) ABSTRACT

A plurality of detection electrodes, connection electrodes, and wires are integrally formed on one surface of a light guide to produce a capacitance-type sensor integral with the light guide. The electrodes are partially formed on a curved portion of the light guide. A resin layer allows an outer case and the light guide to be tightly secured to each other.

### CLAIM OF PRIORITY

This application is a Continuation of International Application No. PCT/JP2008/063877 filed on Aug. 1, 2008, which claims benefit of the Japanese Patent Application No. 2007-205142 filed on Aug. 7, 2007, both of which are hereby incorporated by reference.

### BACKGROUND OF THE INVENTION

1. Field of the Invention

The present invention relates to a capacitance-type sensor integral with a light guide, the sensor having a sensor function and a light guide function.

2. Description of the Related Art

Japanese Unexamined Patent Application Publications Nos. 2006-164672 and 2007-068173 disclose techniques related to the present invention.

Japanese Unexamined Patent Application Publication No. 2006-164672 discloses an apparatus in which a capacitance-type sensor is attached to a light guide. In this apparatus, light emitted from light sources illuminates a mirror from the back side through the light guide. At the same time, the capacitance-type sensor detects a human body and turns on and off the light sources. Specifically, when a human body approaches the capacitance-type sensor, the sensor detects it and switches the operation mode of the light sources. Thus, the mirror is illuminated from the back side and the front side of the mirror is lit up brightly.

Japanese Unexamined Patent Application Publication No. 2007-068173 discloses a technique related to an electronic device including a light guide and having an illuminating function. In this electronic device, light emitting parts are inserted in their corresponding accommodating parts formed in the light guide. Light emitted from the light emitting parts propagates along the light guide and is guided by light guiding parts formed in a touch pad. Then, the light illuminates various touch keys on a main body.

The apparatus disclosed in Japanese Unexamined Patent Application Publication No. 2006-164672 has a configuration in which the light guide and the capacitance-type sensor are produced separately. Therefore, it is difficult to reduce costs involved in manufacturing the apparatus.

Also, in the apparatus disclosed in Japanese Unexamined Patent Application Publication No. 2006-164672, an electrode constituting the capacitance-type sensor has a planar shape. This poses no problem as long as a securing surface, such as a mirror, to which the capacitance-type sensor is secured is flat. However, if the securing surface is a curved surface, it is difficult to attach the capacitance-type sensor to the securing surface. That is, an unnecessary gap is created between the electrode surface and the curved surface. This reduces the capacitance of the capacitance-type sensor and makes it difficult to achieve high detection accuracy.

The present invention has been made to solve the problems described above. The present invention provides a capacitance-type sensor that makes it possible to reduce costs by reducing the number of components, and is capable of providing high detection accuracy.

### SUMMARY OF THE INVENTION

According to an aspect of the present invention, a capacitance-type sensor includes a light guide and a plurality of electrodes integrally formed on one surface of the light guide. The capacitance-type sensor detects a capacitance formed between an object approaching the other surface of the light guide and any of the electrodes.

Since the electrodes of the capacitance-type sensor are integrally formed on the light guide, it is possible to reduce manufacturing costs. At the same time, the capacitance-type sensor can be easily attached to the inside of an electronic device.

For example, the light guide may have a curved portion, and the electrodes may be formed on an inner surface of the curved portion.

Since this can prevent easy creation of an unnecessary gap (air space) between the electrodes and the curved portion of the light guide, it is possible to maintain high detection accuracy of the capacitance-type sensor.

It is preferable that the light guide be disposed on a substrate having a plurality of light sources thereon, and be positioned such that light emitted from the light sources enters the light guide.

With this configuration, light emitted from the light sources can be efficiently guided into the light guide.

It is preferable that the other surface of the light guide, the other surface not having the electrodes thereon, be provided with a resin layer to be in close contact with an outer case of an electronic device to which the light guide is to be attached.

This configuration ensures close contact between the light guide and the outer case and prevents an air space from being created therebetween. Thus, it is possible to prevent sensitivity of the capacitance-type sensor from being degraded, and prevent a loss of light caused by a difference in refractive index.

It is preferable that the resin layer contain a light diffusing agent or a fluorescent agent.

This makes it possible to diffuse light or the like and thus to prevent unevenness of light (formation of hot spots). Therefore, for example, it is possible to evenly illuminate the outer case.

It is preferable that the light guide have a plurality of hooking portions for securing the light guide to the substrate, and that the substrate have a plurality of contacts in contact with their corresponding electrodes and a plurality of hooked portions hooked with their corresponding hooking portions. It is then preferable that when the hooking portions are hooked with their corresponding hooked portions, the contacts be connected to their corresponding electrodes and the light sources be positioned opposite their corresponding incident portions of the light guide.

With this configuration, the capacitance-type sensor integral with the light guide can be easily attached to the electronic device. Additionally, the light sources can be placed opposite their corresponding incident portions simultaneously with connecting the connectors to their corresponding connection electrodes.

According to an embodiment of the present invention, since the electrodes of the capacitance-type sensor are formed on the light guide, it is possible to reduce the number of components and manufacturing costs.

It has been conventionally difficult to form electrodes at a corner and a curved portion of a light guide. According to an embodiment of the present invention, however, electrodes can be formed at such portions of the light guide with high accuracy. It is thus possible to improve the degree of design freedom.

### BRIEF DESCRIPTION OF THE DRAWINGS

FIG. 1 is a cross-sectional view partially illustrating a configuration of an electronic device including a capacitance-type sensor integral with a light guide, according to an embodiment of the present invention.

FIG. 2 is a perspective view of the capacitance-type sensor.

FIG. 3 is a perspective view of a substrate and the capacitance-type sensor as viewed from a direction different from that in FIG. 2.

FIG. 4A and FIG. 4B are cross-sectional views of a connector connected to the capacitance-type sensor. FIG. 4A is a cross-sectional view illustrating a state in which the connector is brought into contact with the capacitance-type sensor. FIG. 4B is a cross-sectional view illustrating a state after the connector is connected to the capacitance-type sensor.

FIG. 5A to FIG. 5C illustrate steps of manufacturing the capacitance-type sensor using an in-mold process.

### DESCRIPTION OF THE PREFERRED EMBODIMENTS

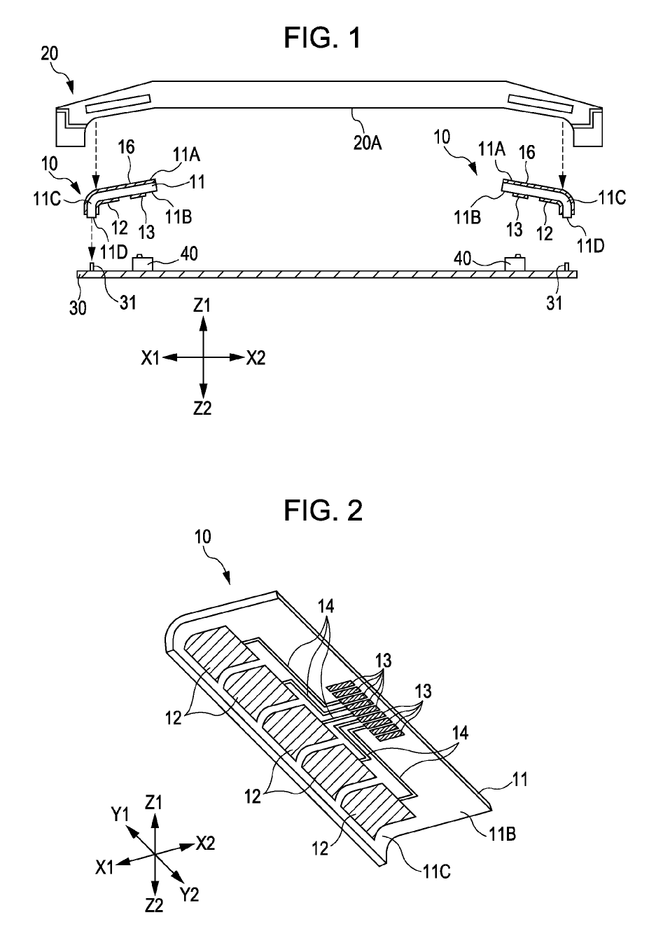

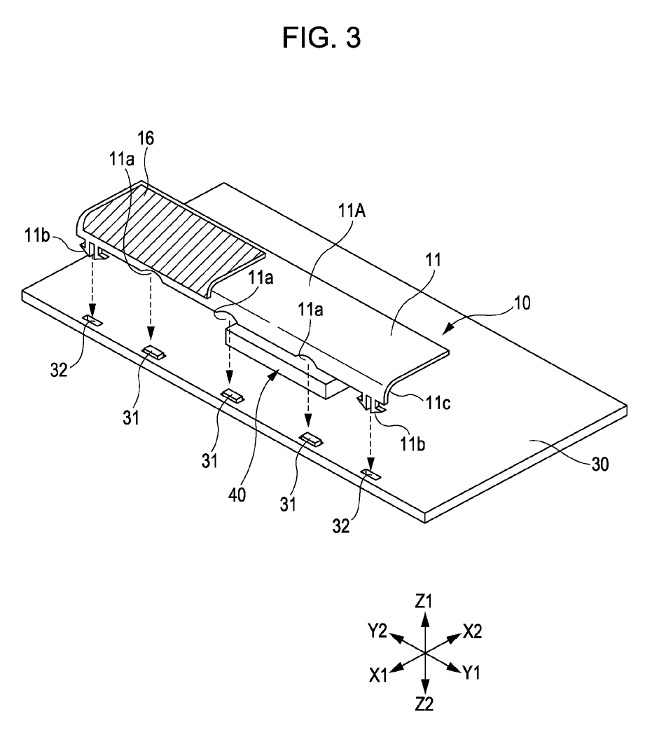

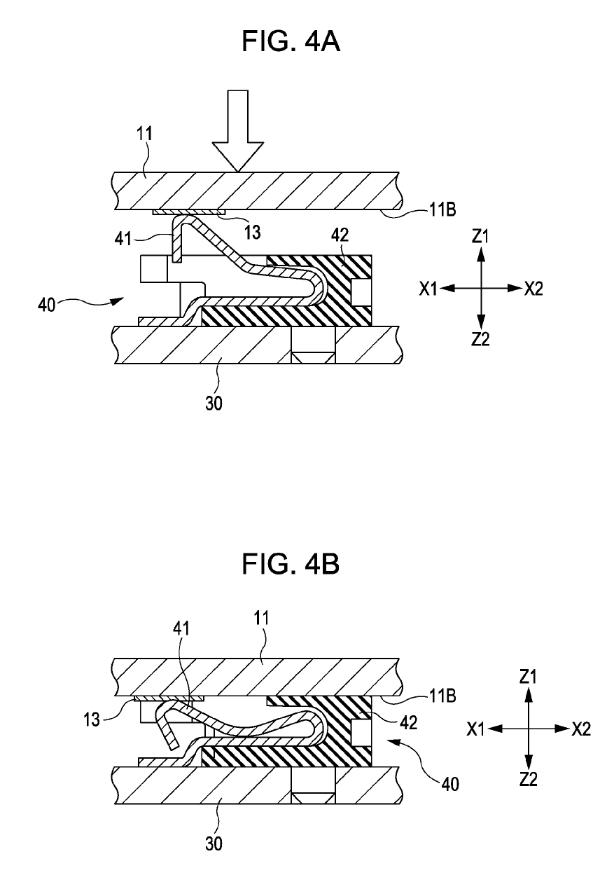

FIG. 1 is a cross-sectional view partially illustrating a configuration of an electronic device including a capacitance-type sensor integral with a light guide, according to an embodiment of the present invention. FIG. 2 is a perspective view of the capacitance-type sensor. FIG. 3 is a perspective view of a substrate and the capacitance-type sensor as viewed from a direction different from that in FIG. 2. FIG. 4A and FIG. 4B are cross-sectional views of a connector connected to the capacitance-type sensor. FIG. 4A is a cross-sectional view illustrating a state in which the connector is brought into contact with the capacitance-type sensor. FIG. 4B is a cross-sectional view illustrating a state after the connector is connected to the capacitance-type sensor. Note that the illustration of an outer case is omitted in FIG. 2 and FIG. 3.

Examples of the electronic device illustrated in FIG. 1 include, but are not limited to, a mobile phone, an electronic dictionary, and a portable music player. A capacitance-type sensor 10 (hereinafter simply referred to as “sensor”) according to an embodiment of the present invention is attached to such an electronic device.

As illustrated in FIG. 2 and FIG. 3, the sensor 10 has a light guide 11 serving as a base. The light guide 11 is made of transparent resin material, such as acryl or polycarbonate. A plurality of detection electrodes 12, connection electrodes 13, and wires 14 for connections between the detection electrodes 12 and their corresponding connection electrodes 13 are disposed on an inner surface 11B of the light guide 11 (i.e., on a lower surface of the light guide 11 in the Z2 direction of the drawings). The detection electrodes 12 are electrodes having a predetermined area. The detection electrodes 12 are provided for forming a capacitance between themselves and an object, such as a human body.

The detection electrodes 12, the connection electrodes 13, and the wires 14 are formed on the inner surface 11B of the light guide 11, in particular, on an inner surface of a curved portion 11C of the light guide 11 by using, for example, an in-mold transfer process (described in detail below). The in-mold transfer process flexibly deals with a non-planar light guide, such as the light guide 11 of FIG. 2, and makes it possible to form detection electrodes on an uneven surface and a corner of the light guide with high accuracy.

Therefore, during formation of the detection electrodes 12 on the light guide 11, it is possible to prevent creation of an unnecessary gap (air space) between the lower surface 11B or curved portion 11C of the light guide 11 and the detection electrodes 12. Thus, a capacitance formed by the detection electrodes 12 can be stabilized.

The sensor 10 is attached to the inside of an outer case 20 covering the electronic device.

With the sensor 10 attached to the inside, the outer case 20 may be fitted into a case of another electronic device.

A plurality of slits (not shown) for illumination are formed in a surface of the outer case 20. The slits are formed by partially removing an outer coating of the outer case 20. In the light guide 11, illuminating parts (not shown) formed on a rough surface are located at positions corresponding to the slits.

As illustrated in FIG. 3, the electronic device has a substrate 30. When the sensor 10 and the outer case 20 are attached to the electronic device, the light guide 11 is positioned opposite the substrate 30.

The substrate 30 is provided with a plurality of light sources 31 and a connector 40. The light sources 31 are preferably, but are not limited to, semiconductor optical elements, such as light-emitting diodes (LEDs).

The light sources 31 are disposed opposite one end face of the light guide 11 constituting the sensor 10. That is, one end 11D (see FIG. 1) of the light guide 11 (i.e., an edge of the curved portion 11C) is opposite the substrate 30. The light sources 31 are disposed on the substrate 30 at positions opposite the end 11D of the light guide 11. As illustrated in FIG. 3, the one end face of the light guide 11 is provided with recessed incident portions 11a. The light sources 31 are disposed inside their corresponding incident portions 11a and face them. The one end face of the light guide 11, the one end face being provided with the incident portions 11a, has hooking portions 11b, at both ends in the Y direction. The hooking portions 11b protruding in the Z2 direction are integral with the light guide 11. The substrate 30 has hooking holes (hooked portions) 32 at positions opposite the hooking portions 11b.

As illustrated in FIG. 3, the connector 40 is disposed near the center of the substrate 30. As illustrated in FIG. 4A and FIG. 4B, the connector 40 has a plurality of elastic contacts 41 formed by bending leaf springs and an insulating holding case 42 that accommodates the elastic contacts 41. The elastic contacts 41 are spaced at predetermined intervals in the Y direction, so that adjacent elastic contacts 41 are insulated from each other. The elastic contacts 41 are elastically deformable at their ends in the Z direction.

As illustrated in FIG. 1, the light guide 11 has a resin layer 16 thereon in an area opposite the outer case 20. The resin layer 16 allows a lower surface 20A of the outer case 20 and an upper surface 11A of the light guide 11 to be tightly secured to each other. This can prevent creation of an unnecessary gap (air space) between the lower surface 20A of the outer case 20 and the upper surface 11A of the light guide 11 and thus can stabilize the capacitance.

Light emitted from the light sources 31 enters the light guide 11 from the incident portions 11 a and propagates through the inside of the light guide 11. Then, the light is output from the illuminating parts (not shown) of the light guide 11 and the slits (not shown) of the outer case 20 to the outside of the electronic device. Thus, the slits of the outer case 20 are brightly illuminated, so that the operator can see the illumination.

It is preferable that the refractive index of the resin layer 16 be greater than that of the light guide 11. This can improve propagation efficiency of light that propagates inside the light guide 11.

The resin layer 16 may contain light diffusing material or fluorescent material. This makes it possible to diffuse light or produce fluorescence in the resin layer 16 on the surface of the light guide 11, and thus to prevent unevenness of light (formation of hot spots). That is, it is possible to provide uniform illumination.

The permittivity e of the resin layer 16 is preferably at least one, and more preferably, three or more. In the sensor 10, when a part of a human body (object), such as an operator's fingertip, approaches or comes into contact with the surface of the outer case 20, a capacitance is formed between the part of the human body and any of the detection electrodes 12. By detecting a change in capacitance with a detecting unit (not shown), the operating state of the operator can be detected. Therefore, when the resin layer 16 is made of material having high permittivity e, a large capacitance can be obtained. This makes it possible to stabilize the detecting operation of the sensor 10.

As illustrated in FIG. 3, the sensor 10 is hooked and secured onto the substrate 30 by inserting the hooking portions 11b of the light guide 11 into their corresponding hooking holes 32 of the substrate 30.

Thus, the incident portions 11a face their corresponding light sources 31. At the same time, the connection electrodes 13 on the inner surface 11B of the light guide 11 come into contact with their corresponding elastic contacts 41 of the connector 40, as illustrated in FIG. 4A.

When the sensor 10 is further pressed, the hooking portions l lb of the light guide 11 are hooked with their corresponding hooking holes 32. The elastic contacts 41 are compressed and significantly elastically deformed in the holding case 42. Since a force that presses back the connection electrodes 13 in the Z1 direction is applied from the elastic contacts 41, the elastic contacts 41 and their corresponding connection electrodes 13 are electrically connected to each other.

Thus, in the capacitance-type sensor 10 integral with the light guide 11 according to an embodiment of the present invention, the light guide 11 can be shaped to fit the outer case 20 that affects the exterior design. Additionally, the detection electrodes 12 can be freely formed on the light guide 11. That is, it has been conventionally difficult to form detection electrodes on a curved portion of a light guide, but according to an embodiment of the present invention, the detection electrodes 12 can be formed on the curved portion 11C etc. with high accuracy. Therefore, the light guide 11 can be shaped to fit the outer case 20. It is thus possible to prevent the shape of the light guide 11 from affecting the design of the outer case 20.

Next, a method for manufacturing the capacitance-type sensor 10 integral with the light guide 11 using the in-mold process will be described.

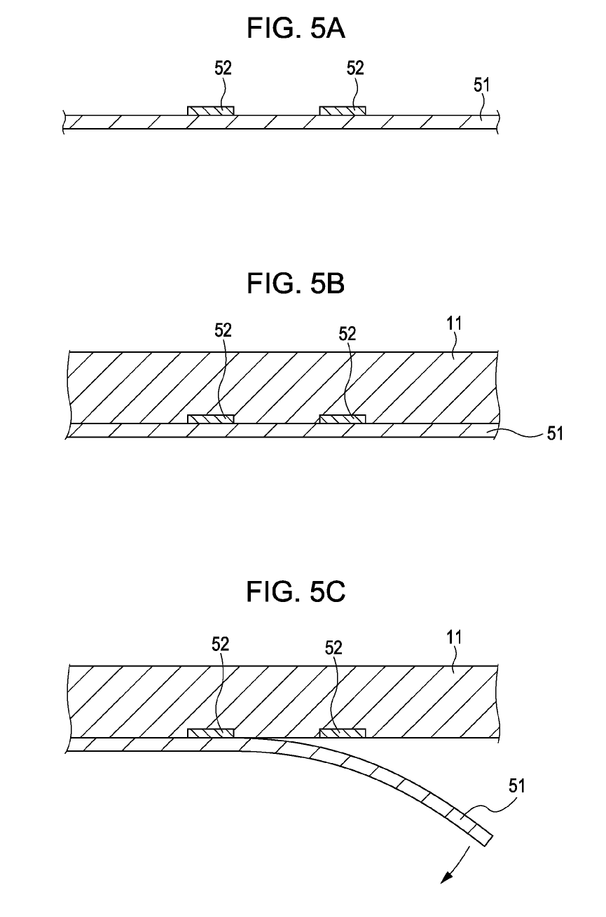

FIG. 5A to FIG. 5C illustrate steps of manufacturing the capacitance-type sensor 10 integral with the light guide 11 using the in-mold process.

In the first step illustrated in FIG. 5A, various electrodes 52 (including the detection electrodes 12, the connection electrodes 13, and the wires 14) are formed on a peel-off sheet 51, such as a polyethylene terephthalate (PET) film, using a screen printing method or the like.

In the second step illustrated in FIG. 5B, the peel-off sheet 51 having the various electrodes 52 thereon is sandwiched by a mold (not shown) for forming the light guide 11 on the peel-off sheet 51. Then, transparent resin material is fed into the mold for injection molding. While the light guide 11 is being injection-molded, the electrodes 52 are transferred to the surface of the light guide 11, so that the light guide 11 and the electrodes 52 are formed integrally.

When the material of the light guide 11 is thermoplastic resin, which is converted into a liquid by applying heat thereto, the thermoplastic resin is subjected to high temperature and pressure in the mold. In this case, since the electrodes 52 are appropriately shaped to fit the mold, it is possible to prevent creation of an air space between the completed light guide 11 and the electrodes 52 in the surface of the light guide 11.

In the third step illustrated in FIG. 5C, the peel-off sheet 51 is peeled off. Thus, the light guide 11 having the various electrodes 52 therein is completed.

As described above, according to an embodiment of the present invention, the electrodes 52 can be formed anywhere in the light guide 11 with high accuracy.

In the first step described above, the electrodes 52 may be formed on both sides of a PET film in which through holes are formed in advance, so that the electrodes 52 formed on one side and the other side are electrically connected to each other via the through holes. In this case, in the second step, if the light guide 11 is injection-molded on one side of the PET film, it is not necessary to carry out the third step in which the PET film is peeled off. This means that the light guide 11 can be used without removing the PET film.

What is claimed is:

1. A capacitance-type sensor comprising:
a light guide; and
a plurality of electrodes integrally formed on one surface of the light guide,
wherein the capacitance-type sensor detects a capacitance formed between an object approaching the other surface of the light guide and any of the electrodes, the other surface not having the electrodes thereon; and
the other surface of the light guide is provided with a resin layer to be in close contact with an outer case of an electronic device to which the light guide is to be attached.

2. The capacitance-type sensor according to claim 1, wherein the light guide has a curved portion, and the electrodes are formed on an inner surface of the curved portion.

3. The capacitance-type sensor according to claim 1, wherein the light guide is disposed on a substrate having a plurality of light sources thereon, and is positioned such that light emitted from the light sources enters the light guide.

4. The capacitance-type sensor according to claim 3, wherein the light guide has a plurality of incident portions configured to receive light emitted from the light sources.

5. The capacitance-type sensor according to claim 4, wherein the incident portions are formed at one end of the light guide.

6. The capacitance-type sensor according to claim 1, wherein the resin layer contains a light diffusing agent or a fluorescent agent.

7. The capacitance-type sensor according to claim 1, wherein a refractive index of the resin layer is greater than that of the light guide.

8. The capacitance-type sensor according to claim 4, wherein the light guide has a plurality of hooking portions for securing the light guide to the substrate;
the substrate has a plurality of contacts in contact with their corresponding electrodes and a plurality of hooked portions hooked with their corresponding hooking portions; and
when the hooking portions are hooked with their corresponding hooked portions, the contacts are connected to their corresponding electrodes and the light sources are positioned opposite their corresponding incident portions of the light guide.
